(19) United States
(12) Patent Application Publication
(10) Pub. No.: US 2026/0140204 A1
(43) Pub. Date: May 21, 2026

(54) SENSOR HAVING NOISE REDUCTION USING CASCADED FILTERS

(71) Applicant: Allegro MicroSystems, LLC, Manchester, NH (US)

(72) Inventors: Nicolas Rigoni, Bedford, NH (US); Matthew Breidenbach, Nashua, NH (US); Mukthar Shareef Shaik, Manchester, NH (US); Sunil Thomas Paul, Nashua, NH (US)

(73) Assignee: Allegro MicroSystems, LLC, Manchester, NH (US)

(21) Appl. No.: 18/952,320

(22) Filed: Nov. 19, 2024

(51) Int. Cl. G01R 33/00; G01D 5/20

(52) U.S. Cl. CPC G01R 33/0029; G01D 5/204

(57) ABSTRACT

Methods and apparatus for a sensor having noise filtering using cascaded filters. A detection module can detect noise above a threshold level and a control module coupled to the detection module can output a control signal based on whether the detection module detects the noise above the threshold level. A filter module includes a first filter and a second filter cascaded with the first filter. The first filter has reconstruction mode to output a signal based on the input prior to detection of the noise above the threshold level. The second filter filters an output of the first filter to smooth the output of the first filter.

### BACKGROUND

As is known in the art, various types of sensors, such as inductive sensors, can be used to detect various types of data. Inductive sensors may be susceptible to coupling noise from surrounding electric motors and/or controllers, which may generate noise spikes. If noise is not properly rejected, such noise may result in out of specification sensor resolution or loss of accuracy.

### SUMMARY

Example embodiments of the disclosure provide methods and apparatus for digital processing of a signal to remove or reduce relatively large noise spikes generated by a source that affects the signal being measured. In embodiments, a motor noise digital filter includes a non-linear module and a linear module. The non-linear module identifies large noise spikes and reconstructs the signal during the spikes. The linear module smooths the result from the non-linear filter.

In one aspect of the disclosure, a method comprises: receiving a sensing element input signal; determining if the input signal includes noise that exceeds a noise threshold; making a control signal active for a selected number of samples after the input signal is determined to exceed the noise threshold; reconstructing the input signal with a nonlinear filter when the control signal is active; and filtering the reconstructed signal with a linear filter that is cascaded with the non-linear filter to smooth the reconstructed filter.

The method can further include one or more of the following features: the input signal is generated by one or more receive coils of an inductive sensor, the noise comprises motor noise spikes, the noise threshold comprises one or more of maximum expected signal acceleration, non-motor noise, and/or expected noise, where determining if the input signal includes noise that exceeds the noise threshold includes performing a second derivative of the input signal, the second derivative comprises acceleration of change in the input signal, storing a last sample of the input sample before determining that the input signal includes noise that exceeds the noise threshold, the control signal is active for a selected amount of time after determining that the input signal includes noise that exceeds the noise threshold, the selected amount of time comprises a number of samples from an ADC that digitizes the input signal, reconstructing the input signal using linear interpolation, and/or reconstructing the input signal using a moving average.

In another aspect, a magnetic field sensor comprises: a filter module having a linear filter and a non-linear filter, the filter configured to: receive a sensing element input signal; determine if the input signal includes noise that exceeds a noise threshold; make a control signal active for a selected number of samples after the input signal is determined to exceed the noise threshold; reconstruct the input signal with the nonlinear filter when the control signal is active; and filter the reconstructed signal with the linear filter that is cascaded with the non-linear filter to smooth the reconstructed filter.

The sensor can further include one or more of the following features: the input signal is generated by one or more receive coils of an inductive sensor, the noise comprises motor noise spikes, the noise threshold comprises one or more of maximum expected signal acceleration, non-motor noise, and/or expected noise, where determining if the input signal includes noise that exceeds the noise threshold includes performing a second derivative of the input signal, the second derivative comprises acceleration of change in the input signal, storing a last sample of the input sample before determining that the input signal includes noise that exceeds the noise threshold, the control signal is active for a selected amount of time after determining that the input signal includes noise that exceeds the noise threshold, the selected amount of time comprises a number of samples from an ADC that digitizes the input signal, reconstructing the input signal using linear interpolation, and/or reconstructing the input signal using a moving average.

### BRIEF DESCRIPTION OF THE DRAWINGS

The foregoing features of this disclosure, as well as the disclosure itself, may be more fully understood from the following description of the drawings in which:

FIG. 1 shows an example sensor having cascaded filters to remove noise from an input signal in accordance with example embodiments of the disclosure;

FIG. 2A shows a block diagram of an example sensor having cascaded first and second filters to reduce motor noise in accordance with example embodiments of the disclosure;

FIG. 2B shows a path through the sensor or FIG. 2A when noise is not detected;

FIG. 2C shows a path through the sensor or FIG. 2A when noise is detected;

FIG. 2D shows an example MATLAB implementation of the sensor of FIG. 2A;

FIG. 3 is a waveform diagram showing an input signal with noise spikes, the input signal after passing through a first filter, and the output after passing through a second filter, and FIG. 3A shows an input signal with noise spikes and an output signal from a known linear filter;

FIG. 4 shows an example sequence of steps for cascaded noise filtering for a sensor in accordance with example embodiments of the disclosure; and

FIG. 5 is a schematic representation of an example computer that can perform at least a portion of the processing described herein.

### DETAILED DESCRIPTION

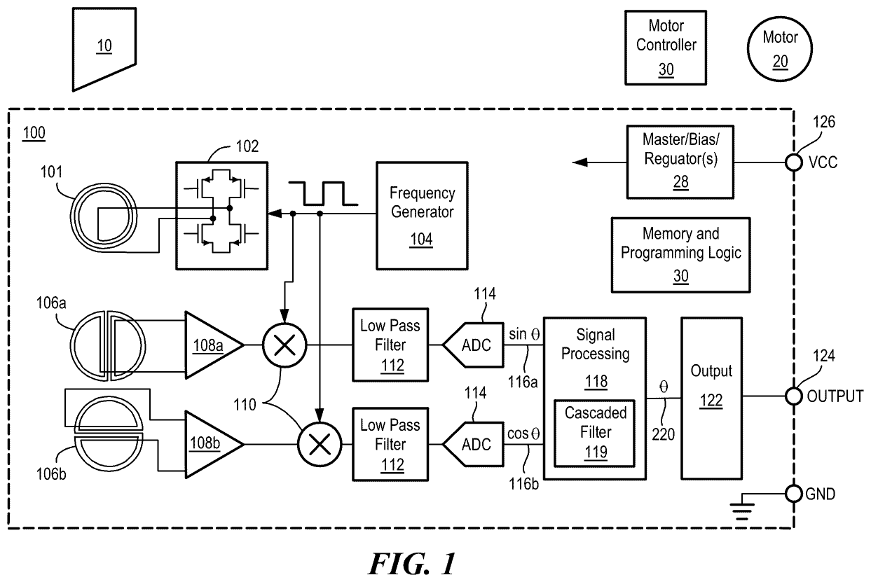

FIG. 1 shows an example inductive sensor IC package 100 having cascaded filtering to filter noise spikes, such as noise spikes generated by a motor 20 controlled by a motor controller 30. In embodiments, the IC package 100 is used in an electric vehicle 120, which may have more sensitivity to noise than non-electric vehicles.

While example embodiments of the disclosure are shown in conjunction with an inductive angle sensor subject to noise spikes from a motor, it is understood that embodiments are applicable to any type of sensor, such as angle, position, speed, current, and the like in which filtering of undesired noise spikes from any type of source is desirable, as well as any type of magnetic field sensor, which may include magnetic field sensing elements.

A main coil 101 is driven by a coil driver 102 coupled to a frequency generator 104, for example. In embodiments, coil driver 102 supplies current to the main coil 101 to generate a magnetic field. An alternating current may be used so that the main coil 101 produces alternating magnetic fields (i.e., magnetic fields with magnetic moments that change over time). The field generated by the main coil 101 causes a reflected signal to be generated by the target 10 that is received by first and second pick up coils 106a,b and amplified by amplifiers 108a,b. In embodiments, the first coil 106a is configured to generate a sine signal and the second coil 106b is configured to generate a cosine signal. As described more fully below, additional coils can be positioned relation to each other to provide harmonic compensation and reduce residual error. The amplified pick up signals for the first and second coils 106a,b are demodulated 110 to bring the high frequency signal down to DC since the magnetic signal will be at the same frequency as that in the main coil, so one uses that same frequency to demodulate down to DC. The sine and cosine signals can be filtered 112, such as with low pass filters 110, and digitized by analog-to-digital converters (ADC) 114.

The digitized sine and cosine signals 116a,b are provided to a signal processing module 118 to generate an angular position signal 120 that corresponds to the angular position θ of the target 10. The signal processing module 118 includes a filter module 119 that includes a non-linear filter and a linear filter, as described more fully below.

In embodiments, the arc tangent function, e.g.,

$${tan}^{- 1} \frac{sin θ}{cos θ} ,$$

can be used to determine angular position θ. In some embodiments, angular position processing is performed in the digital domain. In other embodiments, angular position processing is performed in the analog domain. The angular position signal can be received by an output module 122. In embodiments, the output module can perform signal linearization, calibration, and the like, of the position signal prior to output from the IC, for example, on an output pin 124.

The IC can include an IO pin 126 configured to receive a voltage supply signal VCC. A regulator module 128 can provide voltage signals throughout the IC and provide master bias and other functionality. The IC can further include memory 130 to store programming logic, provide volatile and/or non-volatile memory, and the like.

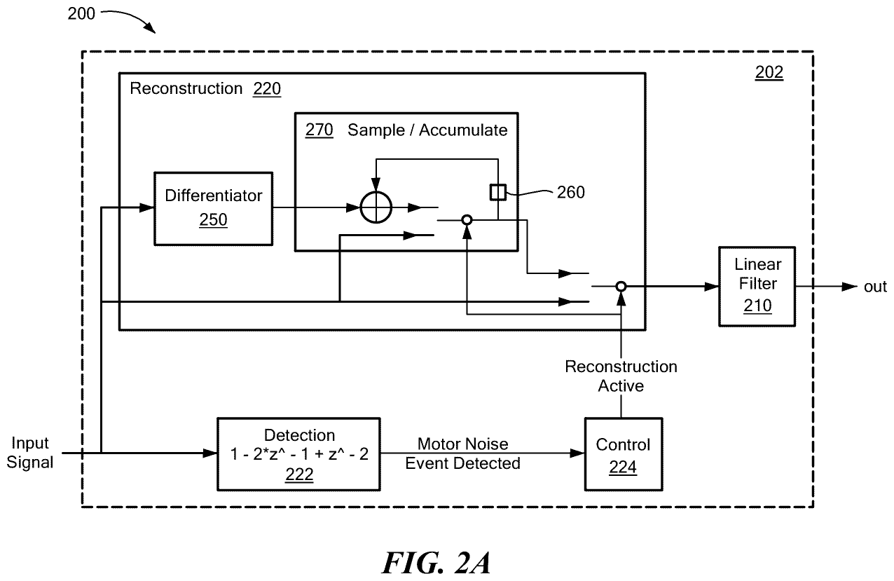

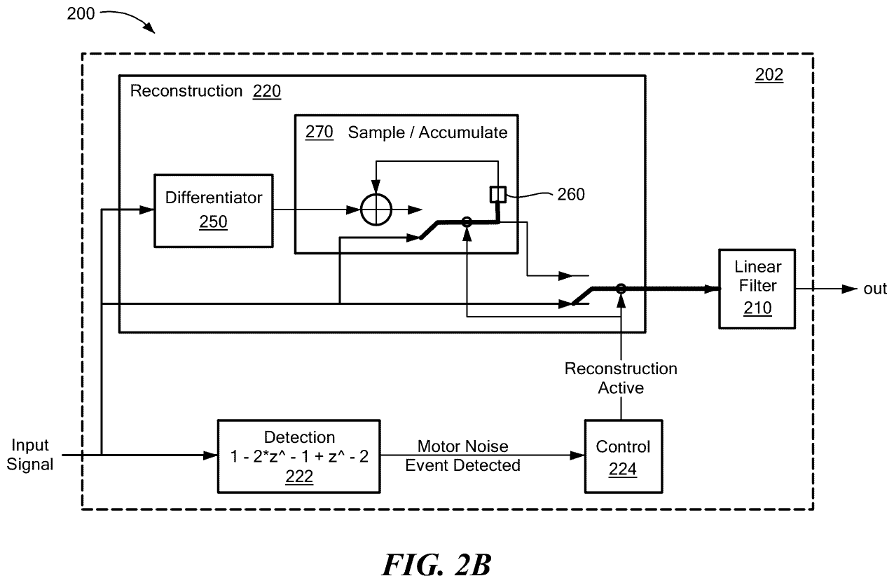

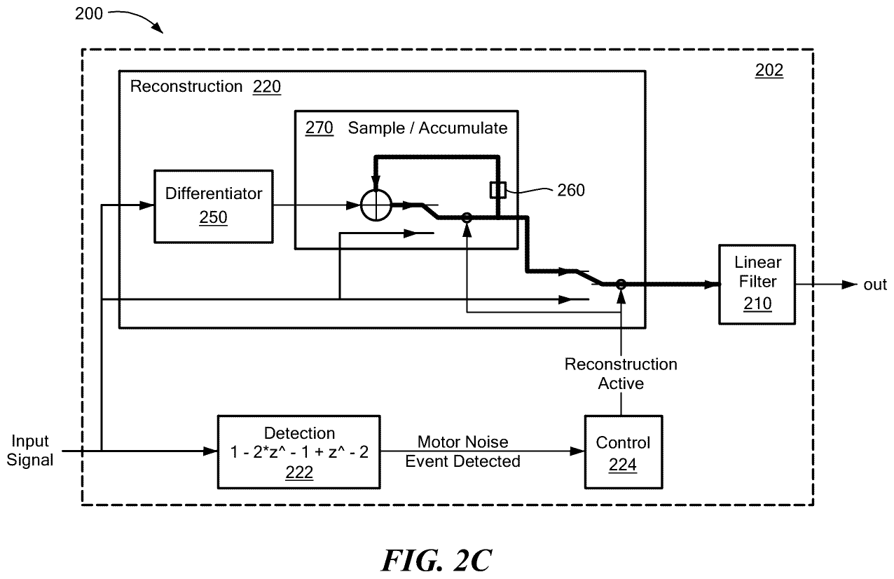

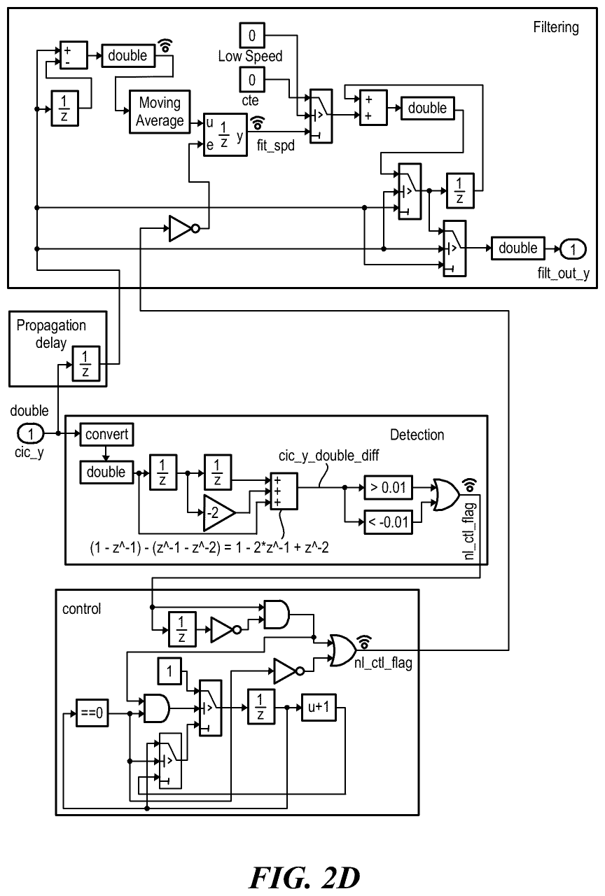

FIGS. 2A-2C are schematic representations of an example sensor 200 having a filter module 202 to reject noise, such as motor noise. Example sensor embodiments digitally process a signal to remove or reduce relatively large noise spikes generated by a noise source that may affect the signal being measured. FIG. 2A shows an example filter module 202 having a linear filter module 210 and a non-linear filter module 220. FIG. 2B shows a signal path for the filter module 202 in a first configuration with no noise detected so there is no signal reconstruction. FIG. 2C shows a signal path for the filter module 202 with signal reconstruction performed by the non-linear module 220, as described more fully below. In general, the non-linear module 220 detects large noise spikes and reconstructs the input signal during the spikes and the linear module 210 smooths the result from the non-linear filter 220.

The linear filter 210 can comprise any suitable type of linear filter of any practical order, e.g., 1^{st}, 2^{nd} or higher order, and can be configured for any bandwidth larger than the signal being measured. In embodiments, the linear filter 210 smooths out the result from the non-linear filter 220 which should have a much higher SNR than the input.

In an example embodiment, the non-linear filter 220 includes a detection module 222 to detect if noise is above a given threshold and provide a detection signal to a control module 224 indicating a noise event has been detected. The control module 224 provides a control signal to the non-linear filter module 220 to indicate when signal reconstruction should be active. Based on the control signal, e.g., when noise is detected, the non-linear filter module 220 reconstructs the input signal to remove noise spikes.

In example embodiments, the control circuit 224 output is active for some number n of samples after detection of noise. In embodiments, the number of samples corresponds to samples taken by an ADC, such as the ADC 114 in FIG. 1. The number of samples should correspond to an expected width of a noise spike.

In the illustrated embodiment, the detection module 222 includes a differentiator for estimating signal acceleration of the input signal. The result is compared to a set of thresholds determined based on the signal dynamics, such as maximum expected acceleration, input non-motor noise, and expected noise. It is understood that the threshold should be set (with some safety margin) above the maximum non-motor noise and maximum expected acceleration, where thresholds are related to the application or expected usage for the sensor.

In embodiments, the detection module 222 includes double signal differentiation for estimating signal acceleration of the input signal. In embodiments, the double differentiator is not affected by constant speed scenarios and effectively identifies the motor noise spike.

The detection module 222 provides an output signal to the control module 224, which sends one or more signals to switches in the non-linear filter to control whether the filter should operate in signal reconstruction mode to interpolate the input signal and thereby filter out the noise spikes. The switches control the signal through the non-linear filter to operate in signal reconstruction mode or normal mode.

The non-linear filter 220 includes a differentiator/derivative module 250, which may perform a first derivative on the input signal, and provides an output to a sample accumulate circuit 270. In embodiments, the sample accumulate circuit 270 of the non-linear filter 220 is active during signal reconstruction operation and uses the last “good” value, e.g., the last value prior to noise detection, which may be stored in a memory element 260. This value is updated with the 1st derivative/differentiation output 250 of the signal. In the illustrated embodiment, the memory element 260 stores the last value of the input signal below the noise threshold.

As will be appreciated, a first derivative 250 may be desirable when the input signal is moving relatively fast. The differentiator module 250 may also include a filter to provide some immunity to thermal noise since consecutive samples that are affected by non-motor noise may negatively affect this derivative.

FIG. 2D shows an example MATLAB implementation of a sensor having a linear filter and a non-linear filter module with a detection and control module to reconstruct an input signal to remove motor noise spikes, such as the sensor of FIG. 2A.

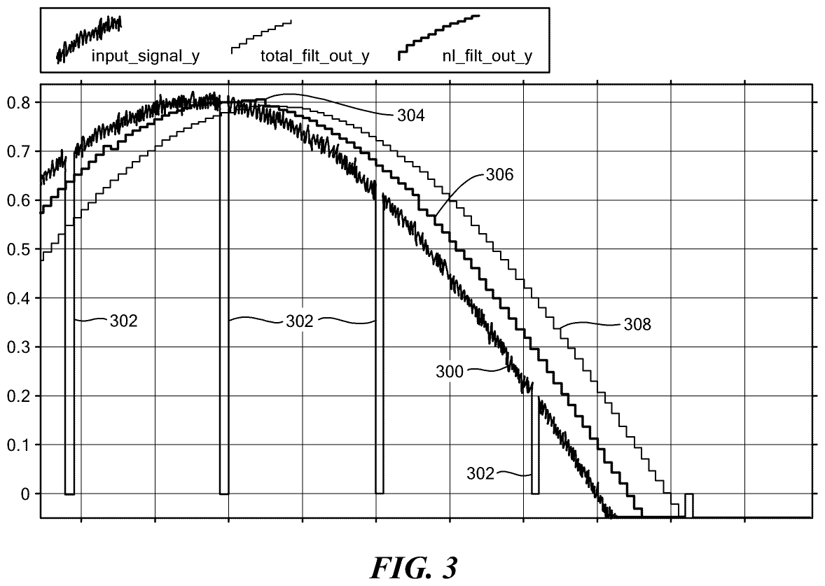

FIG. 3 shows an example waveform showing motor noise spikes 302 injected onto an inductive sensor signal 300. The sensor signal may comprise orthogonal sinusoidal signals. An output of a non-linear filter 304, such as the non-linear filter 220 of FIG. 2B, filters the noise spikes but artifacts from the noise spikes remain. An output of the linear filter 308 smooths the noise artifacts from the non-linear filter.

FIG. 3A shows an input signal 350 with noise spikes 352 and an output signal 354 from a known linear filter, such as a low pass Cascaded Integrator-Comb (CIC) filter. As is known, CIC filters are computationally efficient (FIR) finite impulse response filters having N pairs of integrator and comb sections. The CIC filter (linear filter) is shown as some implementation of digitalization of the input signal by means of a SDM ADC and a cascaded CIC filter for filtering and down sampling. As can be seen, the linear CIC filter does not provide sufficient rejection of the motor noise. Reducing its bandwidth or increasing its order, which are common choices for achieving better noise rejection, does not solve the noise spike problem since the SNR will be too low and/or the motor noise frequency will be within, or too close to, the signal bandwidth. In case those spikes are not properly removed or reduced, the resolution (and even the accuracy) of the sensor is reduced.

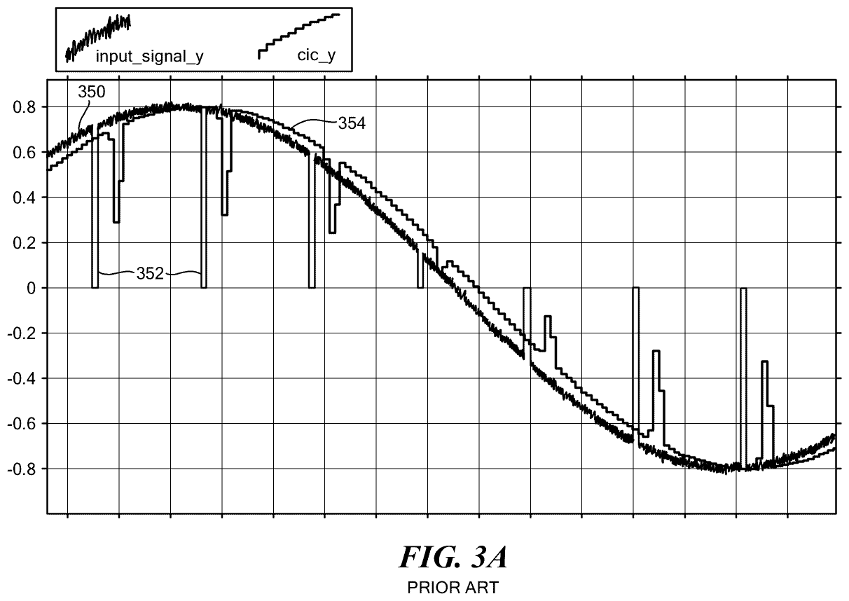

FIG. 4 shows an example sequence of steps for cascaded filtering to reduce motor noise for a sensor in accordance with example embodiments of the disclosure. In step 400, an input signal is received and analyzed to detect noise. In step 402, it is determined whether noise has been detected. If not, in step 404 a non-linear filter processes the signal without reconstruction and in step 406 passes the signal to a linear filter without reconstruction. If so, where noise has been detected, in step 408, the non-linear filter reconstructs the input signal, such as from the last known sample without noise, and passes the signal to the linear filter for smoothing.

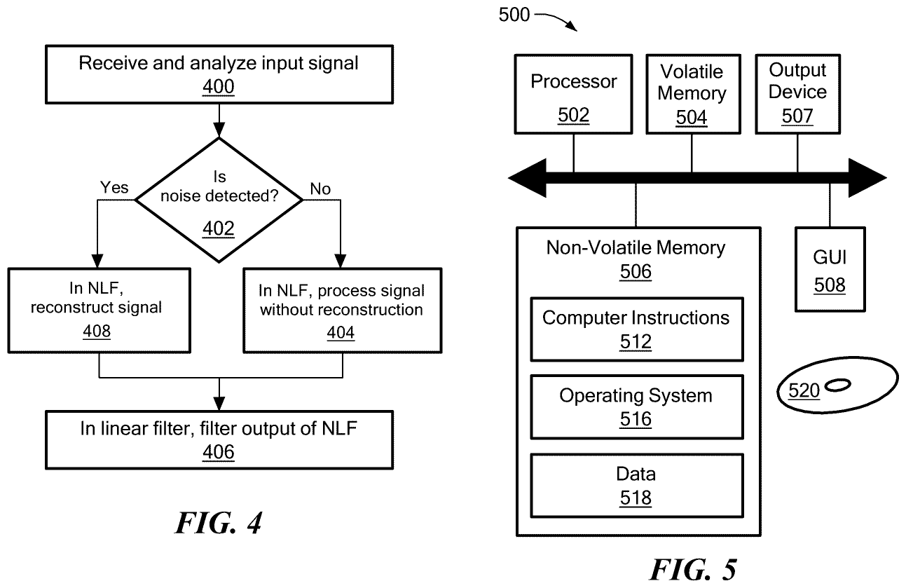

FIG. 5 shows an exemplary computer 500 that can perform at least part of the processing described herein. For example, the computer 500 can perform signal processing and/or filtering control, as described above. It is understood that processing can be performed in any practical order unless an order is explicitly stated or required to perform the processing. The computer 500 includes a processor 502, a volatile memory 504, a non-volatile memory 506 (e.g., hard disk), an output device 507 and a graphical user interface (GUI) 508 (e.g., a mouse, a keyboard, a display, for example). The non-volatile memory 506 stores computer instructions 512, an operating system 516 and data 518. In one example, the computer instructions 512 are executed by the processor 502 out of volatile memory 504. In one embodiment, an article 520 comprises non-transitory computer-readable instructions.

Processing may be implemented in hardware, software, or a combination of the two. Processing may be implemented in computer programs executed on programmable computers/machines that each includes a processor, a storage medium or other article of manufacture that is readable by the processor (including volatile and non-volatile memory and/or storage elements), at least one input device, and one or more output devices. Program code may be applied to data entered using an input device to perform processing and to generate output information.

The system can perform processing, at least in part, via a computer program product, (e.g., in a machine-readable storage device), for execution by, or to control the operation of, data processing apparatus (e.g., a programmable processor, a computer, or multiple computers). Each such program may be implemented in a high-level procedural or object-oriented programming language to communicate with a computer system. However, the programs may be implemented in assembly or machine language. The language may be a compiled or an interpreted language and it may be deployed in any form, including as a stand-alone program or as a module, component, subroutine, or other unit suitable for use in a computing environment. A computer program may be deployed to be executed on one computer or on multiple computers at one site or distributed across multiple sites and interconnected by a communication network. A computer program may be stored on a storage medium or device (e.g., CD-ROM, hard disk, or magnetic diskette) that is readable by a general or special purpose programmable computer for configuring and operating the computer when the storage medium or device is read by the computer.

Processing may also be implemented as a machine-readable storage medium, configured with a computer program, where upon execution, instructions in the computer program cause the computer to operate.

Processing may be performed by one or more programmable embedded processors executing one or more computer programs to perform the functions of the system. All or part of the system may be implemented as special purpose logic circuitry (e.g., an FPGA (field programmable gate array) and/or an ASIC (application-specific integrated circuit)).

Having described exemplary embodiments of the disclosure, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A method, comprising:
receiving a sensing element input signal;
determining if the input signal includes noise that exceeds a noise threshold;
making a control signal active for a selected number of samples after the input signal is determined to exceed the noise threshold;
reconstructing the input signal with a nonlinear filter when the control signal is active; and
filtering the reconstructed signal with a linear filter that is cascaded with the non-linear filter to smooth the reconstructed filter.

2. The method according to claim 1, wherein the input signal is generated by one or more receive coils of an inductive sensor.

3. The method according to claim 1, wherein the noise comprises motor noise spikes.

4. The method according to claim 1, wherein the noise threshold comprises one or more of maximum expected signal acceleration, non-motor noise, and/or expected noise.

5. The method according to claim 1, wherein determining if the input signal includes noise that exceeds the noise threshold includes performing a second derivative of the input signal.

6. The method according to claim 5, wherein the second derivative comprises acceleration of change in the input signal.

7. The method according to claim 1, further including storing a last sample of the input sample before determining that the input signal includes noise that exceeds the noise threshold.

8. The method according to claim 1, wherein the control signal is active for a selected amount of time after determining that the input signal includes noise that exceeds the noise threshold.

9. The method according to claim 8, wherein the selected amount of time comprises a number of samples from an ADC that digitizes the input signal.

10. The method according to claim 1, further including reconstructing the input signal using linear interpolation.

11. The method according to claim 1, further including reconstructing the input signal using a moving average.

12. A magnetic field sensor, comprising:
a filter module having a linear filter and a non-linear filter, the filter configured to:
receive a sensing element input signal;
determine if the input signal includes noise that exceeds a noise threshold;
make a control signal active for a selected number of samples after the input signal is determined to exceed the noise threshold;
reconstruct the input signal with the nonlinear filter when the control signal is active; and
filter the reconstructed signal with the linear filter that is cascaded with the non-linear filter to smooth the reconstructed filter.

13. The sensor according to claim 12, wherein the input signal is generated by one or more receive coils of an inductive sensor.

14. The sensor according to claim 12, wherein the noise comprises motor noise spikes.

15. The sensor according to claim 12, wherein the noise threshold comprises one or more of maximum expected signal acceleration, non-motor noise, and/or expected noise.

16. The sensor according to claim 12, wherein determining if the input signal includes noise that exceeds the noise threshold includes performing a second derivative of the input signal.

17. The sensor according to claim 15, wherein the second derivative comprises acceleration of change in the input signal.

18. The sensor according to claim 12, wherein the sensor is configured to store a last sample of the input sample before determining that the input signal includes noise that exceeds the noise threshold.

19. The sensor according to claim 12, wherein the control signal is active for a selected amount of time after determining that the input signal includes noise that exceeds the noise threshold.

20. The sensor according to claim 19, wherein the selected amount of time comprises a number of samples from an ADC that digitizes the input signal.

21. The sensor according to claim 12, wherein the filter module is further configured to reconstruct the input signal using linear interpolation.

22. The sensor according to claim 12, wherein the filter module is further configured to reconstruct the input signal using a moving average.
